(19) United States
(12) Patent Application Publication
(10) Pub. No.: US 2016/0350179 A1
(43) Pub. Date: Dec. 1, 2016

(54) DECODING METHOD, MEMORY STORAGE DEVICE AND MEMORY CONTROL CIRCUIT UNIT

(71) Applicant: PHISON ELECTRONICS CORP., Miaoli (TW)

(72) Inventors: Wei Lin, Taipei City (TW); Tien-Ching Wang, Kaohsiung City (TW); Kuo-Hsin Lai, Hsinchu County (TW)

(21) Appl. No.: 14/818,323

(22) Filed: Aug. 5, 2015

(30) Foreign Application Priority Data
May 29, 2015 (TW) 104117466

(51) Int. Cl. G06F 11/10; G11C 16/26; G11C 16/08; H03M 13/45; G11C 29/52

(52) U.S. Cl. CPC G06F 11/1068; H03M 13/45; G11C 29/52; G11C 16/08; G11C 16/26

(57) ABSTRACT

A decoding method, a memory storage device and a memory control circuit unit are provided. The method includes: reading a plurality of first memory cells according to a first soft-decision read voltage level to obtain a first soft-decision coding unit belonging to a block code; performing a first soft-decision decoding procedure for the first soft-decision coding unit; if the first soft-decision decoding procedure fails, reading the first memory cells according to a second soft-decision read voltage level to obtain a second soft-decision coding unit belonging to the block code, where a difference value between the first soft-decision read voltage level and the second soft-decision read voltage level is related to a wear degree of the first memory cells; and performing a second soft-decision decoding procedure for the second soft-decision coding unit. Accordingly, a decoding efficiency of block codes may be improved.

### CROSS-REFERENCE TO RELATED APPLICATION

This application claims the priority benefit of Taiwan application serial no. 104117466, filed on May 29, 2015. The entirety of the above-mentioned patent application is hereby incorporated by reference herein and made a part of this specification.

### BACKGROUND

Technical Field

The disclosure relates to a decoding technology, and more particularly, to a decoding method, a memory storage device and a memory control circuit unit.

Description of Related Art

The markets of digital cameras, cellular phones, and MP3 players have expanded rapidly in recent years, resulting in escalated demand for storage media by consumers. The characteristics of data non-volatility, low power consumption, and compact size make a rewritable non-volatile memory module (e.g., flash memory) ideal to be built in the portable multi-media devices as cited above.

Generally, in order to ensure a correctness of data to be stored, the data to be stored is first encoded and then be stored into the rewritable non-volatile memory module. When that data is to be read, the encoded data is read and decoded. If the data can be successfully decoded, it means that there may be only a small number of error bits, and those error bits can be corrected. Otherwise, if the data cannot be successfully decoded (i.e., the decoding fails), more read voltages (also known as soft-decision read voltages) may be used to read more auxiliary decoding information (also known as soft information). According to the auxiliary decoding information, the probability for successfully decoding the data may be improved.

In general, voltage differences among those soft-decision read voltages are fixed and obtained by looking up a table. However, regarding to some rewritable non-volatile memory modules with different usage status, using multiple soft-decision read voltages having the fixed voltage differences may lead to a poor efficiency in the decoding.

Nothing herein should be construed as an admission of knowledge in the prior art of any portion of the present disclosure. Furthermore, citation or identification of any document in this application is not an admission that such document is available as prior art to the present disclosure, or that any reference forms a part of the common general knowledge in the art.

### SUMMARY

The disclosure is directed to a decoding method, a memory storage device and a memory control circuit unit, which are capable of improving a decoding efficiency of block codes.

A decoding method is provided according an exemplary embodiment of the disclosure for a rewritable non-volatile memory module having a plurality of memory cells, and the decoding method includes: determining a first soft-decision read voltage level and a second soft-decision read voltage level according to a wear degree of a plurality of first memory cells among the memory cells, wherein a difference value is provided between the first soft-decision read voltage level and the second soft-decision read voltage level; reading the first memory cells by using the first soft-decision read voltage level to obtain a first soft-decision coding unit, wherein the first soft-decision coding unit belongs to a block code; performing a first soft-decision decoding procedure for the first soft-decision coding unit; if the first soft-decision decoding procedure fails, reading the first memory cells by using the second soft-decision read voltage level to obtain a second soft-decision coding unit, wherein the second soft-decision coding unit belongs to the block code; and performing a second soft-decision decoding procedure for the second soft-decision coding unit.

Another exemplary embodiment of the disclosure provides a memory storage device, which includes a connection interface unit, a rewritable non-volatile memory module and a memory control circuit unit. The connection interface unit is configured to couple to a host system. The rewritable non-volatile memory module includes a plurality of memory cells. The memory control circuit unit is coupled to the connection interface unit and the rewritable non-volatile memory module. The memory control circuit unit is configured to determine a first soft-decision read voltage level and a second soft-decision read voltage level according to a wear degree of a plurality of first memory cells among the memory cells. A difference value is provided between the first soft-decision read voltage level and the second soft-decision read voltage level. The memory control circuit unit is further configured to send a first soft-decision read command sequence. The first soft-decision read command sequence is configured to instruct reading the first memory cells by using the first soft-decision read voltage level to obtain a first soft-decision coding unit. The first soft-decision coding unit belongs to a block code. The memory control circuit unit is further configured to perform a first soft-decision decoding procedure for the first soft-decision coding unit. If the first soft-decision decoding procedure fails, the memory control circuit unit is further configured to send a second soft-decision read command sequence. The second soft-decision read command sequence is configured to instruct reading the first memory cells by using the second soft-decision read voltage level to obtain a second soft-decision coding unit. The second soft-decision coding unit belongs to the block code. The memory control circuit unit is further configured to perform a second soft-decision decoding procedure for the second soft-decision coding unit.

According to another exemplary embodiment of the disclosure, a memory control circuit unit configured to control a rewritable non-volatile memory module is provided. The rewritable non-volatile memory module includes a plurality of memory cells, and the memory control circuit unit includes a host interface, a memory interface, an error checking and correcting circuit and a memory management circuit. The host interface is configured to couple to a host system. The memory interface is configured to couple to a rewritable non-volatile memory module. The memory management circuit is coupled to the host interface, the memory interface and the error checking and correcting circuit. The memory management circuit is configured to determine a first soft-decision read voltage level and a second soft-decision read voltage level according to a wear degree of a plurality of first memory cells among the memory cells. A difference value is provided between the first soft-decision read voltage level and the second soft-decision read voltage level. The memory management circuit is further configured to send a first soft-decision read command sequence. The first soft-decision read command sequence is configured to instruct reading the first memory cells by using the first soft-decision read voltage level to obtain a first soft-decision coding unit. The first soft-decision coding unit belongs to a block code. The error checking and correcting circuit is configured to perform a first soft-decision decoding procedure for the first soft-decision coding unit. If the first soft-decision decoding procedure fails, the memory management circuit is further configured to send a second soft-decision read command sequence. The second soft-decision read command sequence is configured to instruct reading the first memory cells by using the second soft-decision read voltage level to obtain a second soft-decision coding unit. The second soft-decision coding unit belongs to the block code. The error checking and correcting circuit is further configured to perform a second soft-decision decoding procedure for the second soft-decision coding unit.

Based on the above, the disclosure is capable of respectively reading the first soft-decision coding unit and second soft-decision coding unit which belong to the block code according to the first soft-decision read voltage level and the second soft-decision read voltage level having a difference value related to the wear degree of the memory cells, and performing the corresponding soft-decision decoding procedure. Accordingly, a decoding efficiency of block codes may be improved.

To make the above features and advantages of the present disclosure more comprehensible, several embodiments accompanied with drawings are described in detail as follows.

It should be understood, however, that this Summary may not contain all of the aspects and embodiments of the present disclosure, is not meant to be limiting or restrictive in any manner, and that the disclosure as disclosed herein is and will be understood by those of ordinary skill in the art to encompass obvious improvements and modifications thereto.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating a host system and a memory storage device according to an exemplary embodiment of the disclosure.

FIG. 2 is a schematic diagram of a computer, an input/output device, and a memory storage device according to an exemplary embodiment of the disclosure.

FIG. 3 is a schematic diagram illustrating a host system and a memory storage device according to an exemplary embodiment of the disclosure.

FIG. 4 is a schematic block diagram illustrating the memory storage device depicted in FIG. 1.

FIG. 5 is a schematic block diagram illustrating a rewritable non-volatile memory module according to an exemplary embodiment of the disclosure.

FIG. 6 is a schematic diagram illustrating a memory cell array according to an exemplary embodiment of the disclosure.

FIG. 7 is a schematic block diagram illustrating a memory control circuit unit according to an exemplary embodiment of the disclosure.

FIG. 8 is a schematic diagram illustrating management of a rewritable non-volatile memory module according to an exemplary embodiment of the disclosure.

FIG. 9 is a schematic diagram illustrating threshold voltage distributions of a plurality of memory cells according to an exemplary embodiment of the disclosure.

FIG. 10 is a schematic diagram of the block code according to an exemplary embodiment of the disclosure.

FIG. 11 is a schematic diagram illustrating the soft-decision read voltage levels and the threshold voltage distribution states of the memory cells according to an exemplary embodiment of the disclosure.

FIG. 12 is a flowchart illustrating a decoding method according to an exemplary embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Embodiments of the present disclosure may comprise any one or more of the novel features described herein, including in the Detailed Description, and/or shown in the drawings. As used herein, “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

It is to be noted that the term “a” or “an” entity refers to one or more of that entity. As such, the terms “a” (or “an”), “one or more” and “at least one” can be used interchangeably herein.

Generally, a memory storage device (also known as a memory storage system) includes a rewritable non-volatile memory module and a controller (also known as a control circuit). The memory storage device is usually configured together with a host system so that the host system may write data into the memory storage device or read data from the memory storage device.

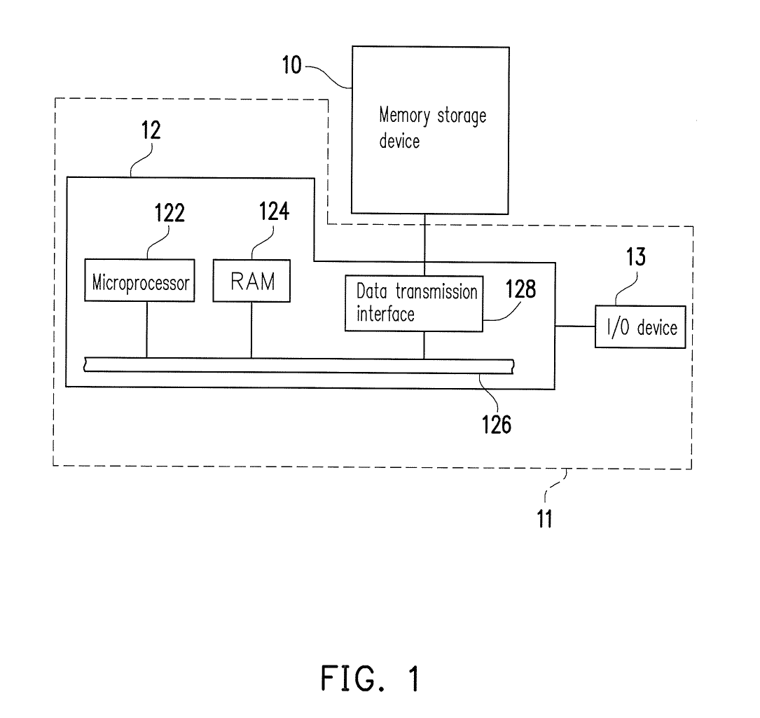

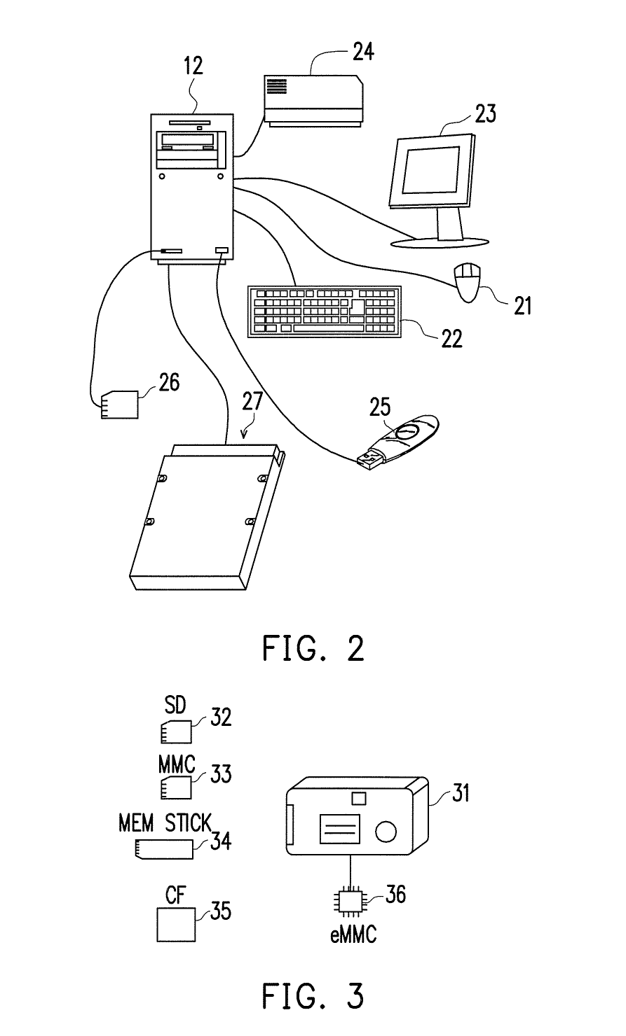

FIG. 1 is a schematic diagram illustrating a host system and a memory storage device according to an exemplary embodiment of the disclosure. FIG. 2 is a schematic diagram of a computer, an input/output device, and a memory storage device according to an exemplary embodiment of the disclosure.

Referring to FIG. 1, a host system 11 includes a computer 12 and an input/output (I/O) device 13. The computer 12 includes a microprocessor 122, a random access memory (RAM) 124, a system bus 126, and a data transmission interface 128. For example, the I/O device 13 includes a mouse 21, a keyboard 22, a display 23 and a printer 24 as shown in FIG. 2. It should be understood that the devices illustrated in FIG. 2 are not intended to limit the I/O device 13, and the I/O device 13 may further include other devices.

In an exemplary embodiment, the memory storage device 10 is coupled to other devices of the host system 11 through the data transmission interface 128. By using the microprocessor 122, the random access memory 124 and the Input/Output (I/O) device 13, data may be written into the memory storage device 10 or may be read from the memory storage device 10. For example, the memory storage device 10 may be a rewritable non-volatile memory storage device such as a flash drive 25, a memory card 26, or a solid state drive (SSD) 27 as shown in FIG. 2.

FIG. 3 is a schematic diagram illustrating a host system and a memory storage device according to an exemplary embodiment of the disclosure.

Generally, the host system 11 may substantially be any system capable of storing data with the memory storage device 10. Even though the host system 11 is illustrated as a computer system in the present exemplary embodiment, however, in another exemplary embodiment of the present disclosure, the host system 11 may be a digital camera, a video camera, a telecommunication device, an audio player, or a video player. For example, when the host system is a digital camera (video camera) 31, the rewritable non-volatile memory storage device may be a SD card 32, a MMC card 33, a memory stick 34, a CF card 35 or an embedded storage device 36 (as shown in FIG. 3). The embedded storage device 36 includes an embedded MMC (eMMC). It should be mentioned that the eMMC is directly coupled to a substrate of the host system.

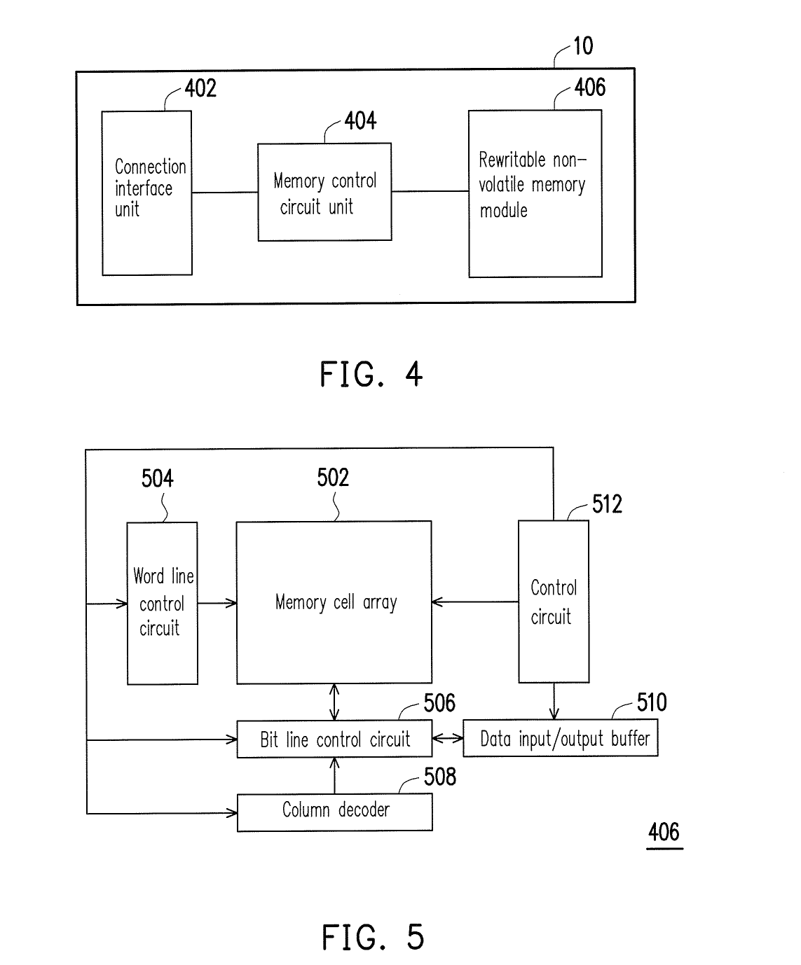

FIG. 4 is a schematic block diagram illustrating the memory storage device depicted in FIG. 1.

Referring to FIG. 4, the memory storage device 10 includes a connection interface unit 402, a memory control circuit unit 404 and a rewritable non-volatile memory module 406.

In the present exemplary embodiment, the connection interface unit 402 is compatible with a serial advanced technology attachment (SATA) standard. Nevertheless, it should be understood that the disclosure is not limited thereto. In another exemplary embodiment, the connection interface unit 402 may also be compatible to a Parallel Advanced Technology Attachment (PATA) standard, an Institute of Electrical and Electronic Engineers (IEEE) 1394 standard, a peripheral component interconnect (PCI) Express interface standard, a universal serial bus (USB) standard, a secure digital (SD) interface standard, a Ultra High Speed-I (UHS-I) interface standard, a Ultra High Speed-II (UHS-II) interface standard, a memory stick (MS) interface standard, a multi media card (MMC) interface standard, an embedded MMC (eMMC) interface standard, a Universal Flash Storage (UFS) interface standard, a compact flash (CF) interface standard, an integrated device electronics (IDE) interface standard or other suitable standards. The connection interface unit 402 and the memory control circuit unit 404 may be packaged into one chip, or the connection interface unit 402 is distributed outside of a chip containing the memory control circuit unit 404.

The memory control circuit unit 404 is configured to execute a plurality of logic gates or control commands which are implemented in a hardware form or in a firmware form and execute operations of writing, reading or erasing data in the rewritable non-volatile memory storage module 406 according to the commands of the host system 11.

The rewritable non-volatile memory module 406 is coupled to the memory control circuit unit 404 and configured to store data written from the host system 11. The rewritable non-volatile memory module 406 may be a Single Level Cell (SLC) NAND flash memory module (i.e., a flash memory module capable of storing one bit data in one memory cell), a Multi Level Cell (MLC) NAND flash memory module (i.e., a flash memory module capable of storing two bit data in one memory cell), a Triple Level Cell (TLC) NAND flash memory module (i.e., a flash memory module capable of storing three bit data in one memory cell), other flash memory modules or any memory module having the same features.

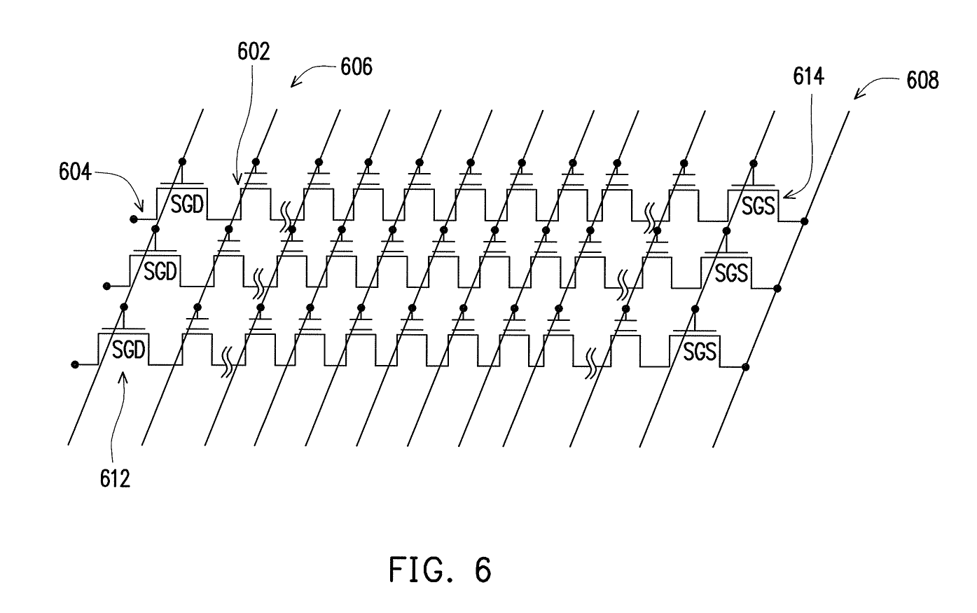

FIG. 5 is a schematic block diagram illustrating a rewritable non-volatile memory module according to an exemplary embodiment of the disclosure. FIG. 6 is a schematic diagram illustrating a memory cell array according to an exemplary embodiment of the disclosure.

Referring to FIG. 5, the rewritable non-volatile memory module 406 includes a memory cell array 502, a word line control circuit 504, a bit line control circuit 506, a column decoder 508, a data input/output buffer 510 and a control circuit 512.

In the present exemplary embodiment, the memory cell array 502 may include a plurality of memory cells 602 used to store data, a plurality of select gate drain (SGD) transistors 612, a plurality of select gate source (SGS) transistors 614, as well as a plurality of bit lines 604, a plurality of word lines 606, a common source line 608 connected to the memory cells (as shown in FIG. 6). The memory cell 602 is disposed at intersections of the bit lines 604 and the word lines 606 in a matrix manner (or in a 3D stacking manner). When a write command or a read command is received from the memory control circuit unit 404, the control circuit 512 controls the word line control circuit 504, the bit line control circuit 506, the column decoder 508, the data input/output buffer 510 to write the data into the memory cell array 502 or read data from the memory cell array 502, wherein the word line control circuit 504 is configured to control voltages applied to the word lines 606, the bit line control circuit 506 is configured to control voltages applied to the bit lines 604, the column decoder 508 is configured to select the corresponding bit line according to a row address in a command, and the data input/output buffer 510 is configured to temporarily store the data.

Each of the memory cells in the rewritable non-volatile memory module 406 may store one or more bits by changing a threshold voltage of the memory cell. More specifically, in each of the memory cells, a charge trapping layer is provided between a control gate and a channel. Amount of electrons in the charge trapping layer may be changed by applying a write voltage to the control gate thereby changing the threshold voltage of the memory cell. This process of changing the threshold voltage is also known as “writing data into the memory cell” or “programming the memory cell”. Each of the memory cells in the memory cell array 502 has a plurality of storage statuses depended on changes in the threshold voltage. Moreover, to which the storage statuses that the memory cell belongs may be determined by applying read voltages, so as to obtain the one or more bits stored in the memory cell.

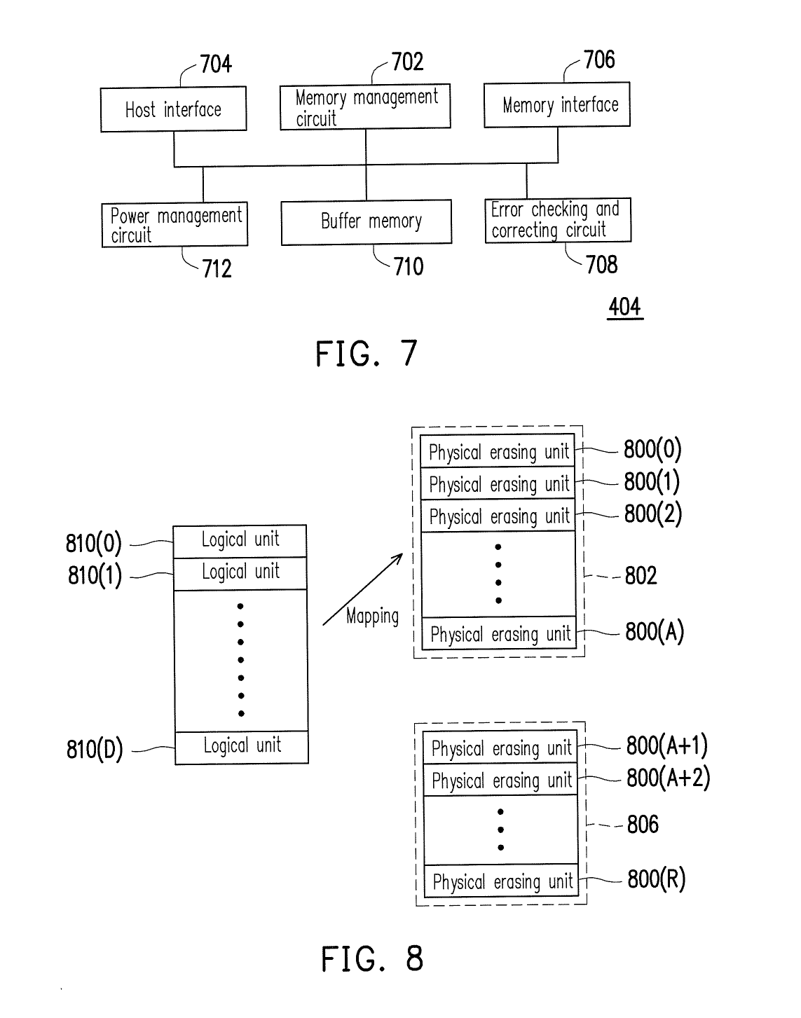

FIG. 7 is a schematic block diagram illustrating a memory control circuit unit according to an exemplary embodiment of the disclosure.

Referring to FIG. 7, the memory control circuit unit 404 includes a memory management circuit 702, a host interface 704, a memory interface 706 and an error checking and correcting circuit 708.

The memory management circuit 702 is configured to control overall operations of the memory control circuit unit 404. Specifically, the memory management circuit 702 has a plurality of control commands. During operations of the memory storage device 10, the control commands are executed to execute various operations such as writing, reading and erasing data. Hereinafter, operations of the memory management circuit 702 are described as equivalent to describe operations of the memory control circuit unit 404.

In the present exemplary embodiment, the control commands of the memory management circuit 702 are implemented in a form of a firmware. For instance, the memory management circuit 702 has a microprocessor unit (not illustrated) and a ROM (not illustrated), and the control commands are burned into the ROM. When the memory storage device 10 operates, the control commands are executed by the microprocessor to perform operations of writing, reading or erasing data.

In another exemplary embodiment, the control commands of the memory management circuit 702 may also be stored as program codes in a specific area (for example, the system area in a memory exclusively used for storing system data) of the rewritable non-volatile memory module 406. In addition, the memory management circuit 702 has a microprocessor unit (not illustrated), the read only memory (not illustrated) and a random access memory (not illustrated). In particular, the ROM has a boot code, which is executed by the microprocessor unit to load the control commands stored in the rewritable non-volatile memory module 406 to the RAM of the memory management circuit 702 when the memory control circuit unit 404 is enabled. Thereafter, the control commands are executed by the microprocessor unit to execute operations of writing, reading or erasing data.

Further, in another exemplary embodiment, the control commands of the memory management circuit 702 may also be implemented in a form of hardware. For example, the memory management circuit 702 includes a microprocessor, a memory cell management circuit, a memory writing circuit, a memory reading circuit, a memory erasing circuit and a data processing circuit. The memory cell management circuit, the memory writing circuit, the memory reading circuit, the memory erasing circuit and the data processing circuit are coupled to the microprocessor. The memory cell management circuit is configured to manage the physical erasing units of the rewritable non-volatile memory module 406; the memory writing circuit is configured to issue a write command sequence to the rewritable non-volatile memory module 406 in order to write data into the rewritable non-volatile memory module 406; the memory reading circuit is configured to issue a read command sequence to the rewritable non-volatile memory module 406 in order to read data from the rewritable non-volatile memory module 406; the memory erasing circuit is configured to issue an erase command sequence to the rewritable non-volatile memory module 406 in order to erase data from the rewritable non-volatile memory module 406; the data processing circuit is configured to process both the data to be written to the rewritable non-volatile memory module 406 and the data to be read from the rewritable non-volatile memory module 406. Each of the write command sequence, the read command sequence and the erase command sequence may include one or more program codes or command codes, respectively and be configured to instruct the rewritable non-volatile memory module 406 to perform the corresponding operations, such as writing, reading and erasing.

The host interface 704 is coupled to the memory management circuit 702 and configured to receive and identify commands and data sent from the host system 11. In other words, the commands and data sent from the host system 11 are transmitted to the memory management circuit 702 through the host interface 704. In the present exemplary embodiment, the host interface 704 is compatible with the SATA standard. However, it should be understood that the present disclosure is not limited thereto, and the host interface 704 may also be compatible with a PATA standard, an IEEE 1394 standard, a PCI Express standard, a USB standard, a SD standard, a UHS-I standard, a UHS-II standard, a MS standard, a MMC standard, a eMMC standard, a UFS standard, a CF standard, an IDE standard, or other suitable standards for data transmission.

The memory interface 706 is coupled to the memory management circuit 702 and configured to access the rewritable non-volatile memory module 406. That is, data to be written to the rewritable non-volatile memory module 406 is converted to a format acceptable to the rewritable non-volatile memory module 406 through the memory interface 706. Specifically, if the memory management circuit 702 intends to access the rewritable non-volatile memory module 406, the memory interface 706 sends corresponding command sequences. For example, the command sequences may include the write command sequence which instructs to write data, the read command sequence which instructs to read data, the erase command sequence which instructs to erase data, and other corresponding command sequences configured to instruct performing various memory operations (e.g., for changing read voltage levels or performing a garbage collection procedure). Detailed descriptions regarding the above are omitted herein. These command sequences are generated by the memory management circuit 702 and transmitted to the rewritable non-volatile memory module 406 through the memory interface 706, for example. The command sequences may include one or more signals, or data transmitted in the bus. The signals or the data may include command codes and programming codes. For example, in a read command sequence, information such as identification codes and memory addresses are included.

The error checking and correcting circuit 708 is coupled to the memory management circuit 702 and configured to execute an error checking and correcting process to ensure the correctness of data. Specifically, when the memory management circuit 702 receives the write command from the host system 11, the error checking and correcting circuit 708 generates an error correcting code (ECC) and/or an error detecting code (EDC) for data corresponding to the write command, and the memory management circuit 702 writes the data and the corresponding ECC and/or the EDC to the rewritable non-volatile memory module 406. Later, when the memory management circuit 702 reads the data from the rewritable non-volatile memory module 406, the corresponding ECC and/or the EDC are also read, and the error checking and correcting circuit 708 executes the error checking and correcting procedure on the read data based on the ECC and/or the EDC.

In an exemplary embodiment, the memory control circuit unit 404 further includes a buffer memory 710 and a power management circuit 712. The buffer memory 710 is coupled to the memory management circuit 702 and configured to temporarily store data and commands from the host system 11 or data from the rewritable non-volatile memory module 406. The power management unit 712 is coupled to the memory management circuit 702 and configured to control a power of the memory storage device 10.

FIG. 8 is a schematic diagram illustrating management of a rewritable non-volatile memory module according to an exemplary embodiment of the disclosure. It should be understood that terms, such as “select”, “group”, “divide”, “associate” and so forth, are logical concepts which describe operations in the physical erasing units of the rewritable non-volatile memory module 406. That is, the physical erasing units of the rewritable non-volatile memory module are logically operated, but actual positions of the physical erasing units of the rewritable non-volatile memory module are not changed.

The memory cells of the rewritable non-volatile memory module 406 constitute a plurality of physical programming units, and the physical programming units constitute a plurality of physical erasing units. Specifically, the memory cells on the same word line constitute one or more of the physical programming units. If each of the memory cells can store more than two bits, the physical programming units on the same word line can be at least classified into a lower physical programming unit and an upper physical programming unit. For instance, a least significant bit (LSB) of one memory cell belongs to the lower physical programming unit, and a most significant bit (MSB) of one memory cell belongs to the upper physical programming unit. Generally, in the MLC NAND flash memory, a writing speed of the lower physical programming unit is faster than a writing speed of the upper physical programming unit, or a reliability of the lower physical programming unit is higher than a reliability of the upper physical programming unit. In the present exemplary embodiment, the physical programming unit is a minimum unit for programming. That is, the programming unit is the minimum unit for writing data. For example, the physical programming unit is a physical page or a physical sector. When the physical programming unit is the physical page, each physical programming unit usually includes a data bit area and a redundancy bit area. The data bit area has multiple physical sectors configured to store user data, and the redundant bit area is configured to store system data (e.g., an error correcting code). In the present exemplary embodiment, the data bit area contains 32 physical sectors, and a size of each physical sector is 512-byte (B). However, in other exemplary embodiments, the data bit area may also include 8, 16 physical sectors, or different number (more or less) of the physical sectors, and the number and a size of the physical sectors are not limited in the disclosure. On the other hand, the physical erasing unit is the minimal unit for erasing. Namely, each physical erasing unit contains the least number of memory cells to be erased together. For instance, the physical erasing unit is a physical block.

Referring to FIG. 8, the memory management circuit 702 may logically group the physical erasing units 800(0) to 800(R) of the rewritable non-volatile memory module 406 into a plurality of areas such as a storage area 802 and a system area 806.

The physical erasing units in the storage area 802 are configured to store data from the host system 11. The storage area 802 stores valid data and invalid data. For example, when the host system 11 intends to delete one valid data, the data being deleted may still be stored in the storage area 802 but marked as the invalid data. The physical erasing unit not storing the valid data is also known as a spare physical erasing unit. For example, the physical erasing unit being erased may become the spare physical erasing unit. If there are damaged physical erasing units in the storage area 802 or the system area 806, the physical erasing units in the storage area 802 may also be used to replace the damaged physical erasing units. If there are no available physical erase units in the storage area 802 for replacing the damaged physical erasing units, the memory management circuit 702 may announce that the memory storage device 10 is in a write protect status, so that data can no longer be written thereto. In addition, the physical erasing unit storing the valid data is also known as a non-spare physical erasing unit.

The physical erasing units in the system area 806 are configured to record system information including information related to manufacturer and model of a memory chip, a number of physical erasing units in the memory chip, a number of the physical programming unit in each physical erasing unit, and so forth.

Amounts of the physical erasing units in the storage area 802 and the system area 806 may be different to each other based on the different memory specifications. In addition, it should be understood that, during operations of the memory storage device 10, grouping relations of the physical erasing units associated to the storage area 802 and the system area 806 may be dynamically changed. For example, when damaged physical erasing units in the system area 806 are replaced by the physical erasing units in the storage area 802, the physical erasing units originally in the storage area 802 are then associated to the system area 806.

The memory management circuit 702 configures the logical units 810(0) to 810(D) for mapping to the physical erasing units 800(0) to 800(A) in the storage area 802. For example, in the present exemplary embodiment, the host system 11 accesses the data stored in the storage area 802 through logical addresses. Therefore, each of the logical units 810(0) to 810(D) refers to one logical address. However, in another exemplary embodiment, each of the logical units 810(0) to 810(D) may also refer to one logical programming unit, one logical erasing unit or a composition of a plurality of consecutive logical addresses. Each of the logical units 810(0) to 810(D) maps to one or more physical units. In the present exemplary embodiment, one physical unit refers to one physical erasing unit. However, in another exemplary embodiment, one physical unit may also be one physical address, one physical programming unit, or a composition of a plurality of consecutive physical addresses, which are not particularly limited in the disclosure. The memory management circuit 702 records mapping relations between the logical units and the physical units into at least one logical-to-physical mapping table. When the host system 11 intends to read the data from the memory storage device 10 or write the data into the memory storage device 10, the memory management circuit 702 may access the data in the memory storage device 10 according to the logical-to-physical mapping table.

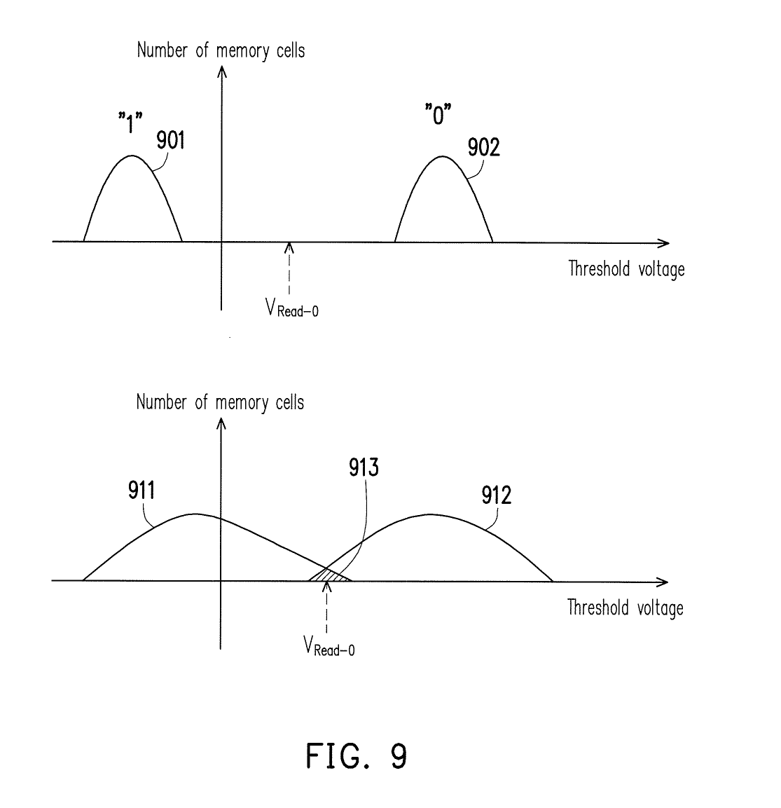

FIG. 9 is a schematic diagram illustrating threshold voltage distributions of a plurality of memory cells according to an exemplary embodiment of the disclosure.

Referring to FIG. 9, a horizontal axis represents the threshold voltage of the memory, and a vertical axis represents a number of the memory cells. For instance, FIG. 9 illustrates the threshold voltage of each memory cell in one specific physical unit. It is assumed that, when the threshold voltage of the specific memory cell falls in a distribution 901, the bit stored in the memory cell is the bit “1”; and if the threshold voltage of a specific memory cell falls within a distribution 902, the bit stored in that specific memory cell is the bit “0”. It is worth mentioning that, in the present exemplary embodiment, each of the memory cells is configured to store one bit, and thus there are two possible distributions of the threshold voltages. However, in other exemplary embodiments, if one memory cell is configured to store a plurality of bits, there can be four, eight, or any other number of possible distributions of the corresponding threshold voltages. In addition, the bit represented by each distribution is not particularly limited in the disclosure. For example, in another exemplary embodiment of FIG. 9, the distribution 901 indicates the bit “0”, and the distribution 902 indicates the bit “1”.

If it is intended to read the data from the rewritable non-volatile memory module 406, the memory management circuit 702 transmits a read command sequence to the rewritable non-volatile memory module 406. The read command sequence is configured to instruct reading one specific logical unit or a plurality of memory cells in one specific physical unit in order to obtain a plurality of bits. For example, according to the read command sequence, the rewritable non-volatile memory module 406 may read the memory cells according to a read voltage level V_{Read-0} and transmit the obtained bit data to the memory management circuit 702. For example, if the threshold voltage of one specific memory cell is less than the read voltage level V_{Read-0} (e.g., the memory cells that belongs to the distribution 901), the bit “1” is read by the memory management circuit 702; and if the threshold voltage of one specific memory cell is greater than the read voltage level V_{Read-0} (e.g., the memory cell that belongs to the distribution 902), the bit “0” is read by the memory management circuit 702.

However, with increases in the usage time and/or changes in an operation environment of the rewritable non-volatile memory module 406, a performance degradation may occur on the distributions 901 and 902. After the performance degradation occurs, the distributions 901 and 902 may gradually move close to each other or to even overlap with each other. For example, a distribution 911 and a distribution 912 are used to represent the distributions 901 and 902 after occurrence of the performance degradation, respectively. The distribution 911 and the distribution 912 include an overlapping area 913 (represented by slash lines). The overlapping area 913 indicates that, some of the memory cells are supposed to store the bit “1” yet having the threshold voltages greater than the read voltage level V_{Read-0}; or, some of the memory cells are supposed to store the bit “0” yet having the threshold voltages less than the read voltage level V_{Read-0}. After the performance degradation occurs, if the read voltage level V_{Read-0} is continually used to read the memory cells belonging to the distribution 911 or the distribution 912, the bits being read may include more errors. For example, the memory cells belonging to the distribution 911 may be mistakenly determined as belonging to the distribution 912, or the memory cells belonging to the distribution 912 may be mistakenly determined as belonging to the distribution 911. Therefore, in the present exemplary embodiment, the error checking and correcting circuit 708 performs a decoding on the read bit data so as to correct the errors therein.

In the present exemplary embodiment, if the data is to be stored into the rewritable non-volatile memory module 406, the error checking and correcting circuit 708 encodes the data to be stored and generates a coding unit. For example, the coding unit is constituted by the decoded data. The coding unit belongs to a block code. Thereafter, the memory management circuit 702 sends the write command sequence to the rewritable non-volatile memory module 406 to instruct storing the coding unit into one specific area in the rewritable non-volatile memory module 406. For example, the specific area may be at least one physical unit and includes a plurality of memory cells (hereinafter, also known as first memory cells). According to the write command sequence, the rewritable non-volatile memory module 406 stores the coding unit into the first memory cells. Later, when the memory management circuit 702 instructs to read the data from the first memory cells, the rewritable non-volatile memory module 406 reads the coding unit from the first memory cells, and the error checking and correcting circuit 708 performs a corresponding decoding procedure to decode the coding unit.

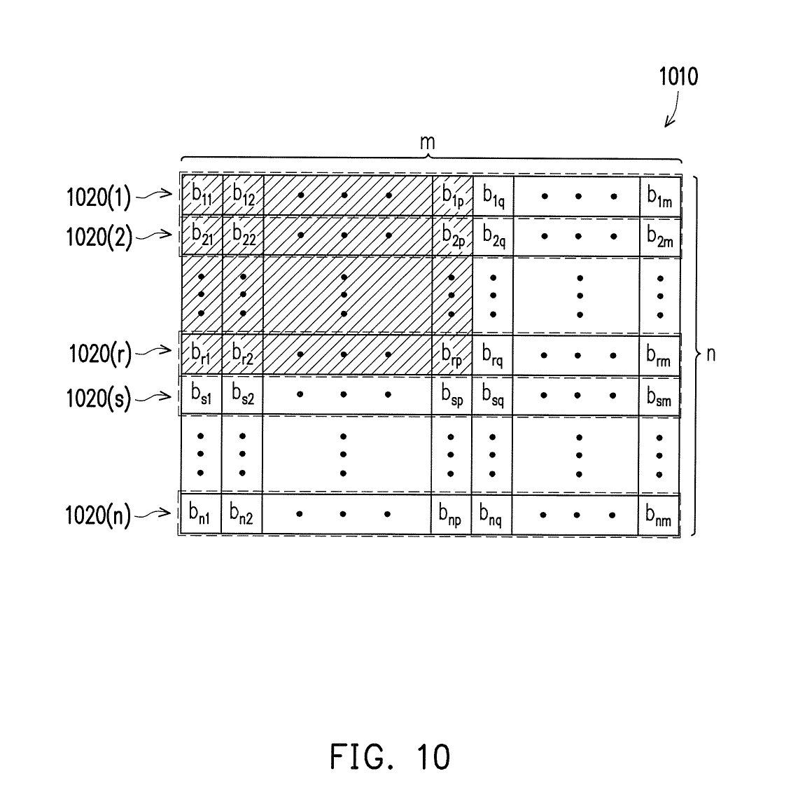

FIG. 10 is a schematic diagram of the block code according to an exemplary embodiment of the disclosure.

Referring to FIG. 10, a coding unit 1010 belongs to the block code and includes bits b₁₁ to bₙₘ. The bits b₁₁ to bₙₘ may be grouped into sub coding units 1020(1) to 1020(n). Each of the sub coding units 1020(1) to 1020(n) has m bits. Noted that, n and m may be any positive integer greater than 1. In the present exemplary embodiment, some of the bits (hereinafter, also known as predetermined bits) in the coding unit 1010 are determined by a plurality of encoding procedures. For example, the encoding procedure having an encoding direction in a row direction (e.g., from the left to the right) may be regarded as a first-type encoding procedure, and the encoding procedure having an encoding direction in a column direction (e.g., from the top to the bottom) may be regarded as a second-type encoding procedure. In the exemplary embodiment, the first-type encoding procedure is also known as a row encoding procedure, and the second-type encoding procedure is also known as a column encoding procedure.

In the present exemplary embodiment, the first-type encoding procedure is first performed, and the second-type encoding procedure is performed subsequently according to an encoding result of the first-type encoding procedure. For example, assuming that the user data to be stored includes the bits b₁₁ to b₁ₚ, b₂₁ to b₂ₚ, bᵣ₁ to bᵣₚ (represented by slash lines), the bits b₁₁ to b₁ₚ, b₂₁ to b₂ₚ, . . . , bᵣ₁ to bᵣₚ are respectively encoded to obtain the bits b₁₁ to b₁ₘ (i.e., the sub coding unit 1020(1)), b₂₁ to b₂ₘ (i.e., the sub coding unit 1020(2)), . . . , bᵣ₁ to bᵣₘ (i.e., the sub coding unit 1020(r)) in the first-type encoding procedure. The bits b_{1q} to b₁ₘ are the error correcting code corresponding to the bits b₁₁ to b₁ₚ; the bits b_{2q} to b₂ₘ are the error correcting code corresponding to b₂₁ to b₂ₚ; the bits b_{rq} to bᵣₘ are the error correcting code corresponding to the bits bᵣ₁ to bᵣₚ; and the rest may be deduced by analogy, where q is equal to p+1. After the sub coding units 1020(1) to 1020(r) are obtained, the second-type encoding procedure is performed. For example, in the second-type encoding procedure, the bits b₁₁ to bᵣ₁ (i.e., first bits of the sub coding units 1020(1) to 1020(r)), the bits b₁₂ to bᵣ₂ (i.e., second bits of the sub coding units 1020(1) to 1020(r)), . . . , the bits b₁ₘ to bᵣₘ (i.e., m^{th} bits of the sub coding units 1020(1) to 1020(r)) are respectively encoded to obtain the bits b₁₁ to bₙ₁, b₁₂ to bₙ₂, . . . , b₁ₘ to bₙₘ. The bits bₛ₁ to bₙ₁ are the error correcting code corresponding to the bits b₁₁ to bᵣ₁; the bits bₛ₂ to bₙ₂ are the error correcting code corresponding to b₁₂ to bᵣ₂; the bits bₛₘ to bₙₘ are the error correcting code corresponding to the bits b₁ₘ to bᵣₘ; and the rest may be deduced by analogy, where s is equal to r+1.

After the coding unit 1010 is read, the coding unit 1010 is decoded in correspondence to the encoding sequence being adopted. For example, in the present exemplary embodiment, a decoding procedure having a decoding direction in the column direction (also known as a second-type decoding procedure) is first performed, and a decoding procedure having a decoding direction in the row direction (also known as a first-type decoding procedure) is performed subsequently according to a decoding result of the second-type decoding procedure. For example, in the second-type decoding procedure, the bits bₛ₁ to bₙ₁, bₛ₂ to bₙ₂, . . . , bₛₘ to bₙₘ are respectively used to decode the bits b₁₁ to bᵣ₁, b₁₂ to bᵣ₂, . . . , b₁ₘ to bᵣₘ. After the decoded bits b₁₁ to bᵣ₁, b₁₂ to bᵣ₂, . . . , b₁ₘ to bᵣₘ are obtained, the first-type decoding procedure is performed. For example, in the first-type decoding procedure, the bits b_{1q} to b₁ₘ, b_{2q} to b₂ₘ, . . . , b_{rq} to bᵣₘ decoded by the second-type decoding procedure are respectively used to decode the bits b₁₁ to b₁ₚ, b₂₁ to b₂ₚ . . . , bᵣ₁ to bᵣₚ to obtain the decoded user data.

It is worth mentioning that, the composition of the coding units and the encoding/decoding sequence as mentioned in the foregoing exemplary embodiments are merely an example instead of limitations to the disclosure. For example, in another exemplary embodiment, the generated error correcting codes may also be arranged in front of the corresponding user data or inserted in the corresponding user data. For example, in an exemplary embodiment, when the user data is to be encoded, it is also possible that the second-type encoding procedure is first performed, and then the first-type encoding procedure is performed according to an encoding result of the second-type encoding procedure; and correspondingly, when the corresponding coding unit is to be decoded, the first-type decoding procedure is first performed, and then the second-type decoding procedure is performed according to a decoding result of the first-type decoding procedure. Furthermore, in another exemplary embodiment, if the first-type encoding procedure is performed before performing the second-type encoding procedure when encoding the user data, the first-type decoding procedure may be performed before performing the second-type decoding procedure when decoding the corresponding coding unit; and Alternatively, if the second-type encoding procedure is performed before performing the first-type encoding procedure when encoding the user data, the second-type decoding procedure may be performed before performing the first-type decoding procedure when decoding the corresponding coding unit.

In the present exemplary embodiment, the first-type encoding procedure (or the first-type decoding procedure) and the second-type encoding procedure (or the second-type decoding procedure) are different in terms of the encoding direction, but the first-type encoding procedure (or the first-type decoding procedure) and the second-type encoding procedure (or the second-type decoding procedure) may adopt the same or different encoding/decoding algorithms. For example, the first-type encoding procedure and the corresponding first-type decoding procedure may include at least one of various encoding/decoding algorithms including a low density parity code (LDPC), a BCH code, a Reed-Solomon code (RS code) and a block turbo code (BTC); whereas the second-type encoding procedure and the corresponding second-type decoding procedure may also include at least one the aforementioned encoding/decoding algorithms or other encoding/decoding algorithms, which are not particularly limited in the disclosure. Further, in another exemplary embodiment of FIG. 10, the directions of the multiple encoding/decoding procedure for generating the coding unit 1010 may also be any directions or satisfy any rules instead of being limited to the row direction and the column direction as described above. For example, in an exemplary embodiment, the encoding may be perform on the bits b₁₁, b₂₂, b₃₃ along a diagonal line direction, and those bits may be decoded in the diagonal line direction during the decoding. Alternatively, in another exemplary embodiment, some rows, some columns or some bits may be skipped when the encoding/decoding is performed.

In the present exemplary embodiment, the memory management circuit 702 receives a read command from the host system 11. The read command instructs to read at least one logical unit mapped to the physical unit where the first memory cells are located, for example. According to the read command, the memory management circuit 702 sends a read command sequence (hereinafter, also known as a hard-decision read command sequence) to the rewritable non-volatile memory module 406. Further, in another exemplary embodiment, the hard-decision read command sequence may be used in any data management procedure of memory module, such as the garbage collection procedure and so on. The hard-decision read command sequence is configured to instruct reading data from the first memory cells by a read voltage level (hereinafter, also known as a hard-decision read voltage level). The hard-decision read voltage level may be assigned in the hard-decision read command sequence or obtained through a table look-up approach by the rewritable non-volatile memory module 406 according to the hard-decision read command sequence. According to the hard-decision read command sequence, the rewritable non-volatile memory module 406 applies one read voltage corresponding to the hard-decision read voltage level (e.g., the read voltage V_{Read-0} in FIG. 9) to the first memory cells so that a plurality of bit data may be transmitted back accordingly. A coding unit (hereinafter, also known as a hard-decision coding unit) is constituted by aforesaid bit data. The hard-decision coding unit belongs to the block code. Description regarding the block code has been introduced in details as above, which is not repeated hereinafter. Then, the error checking and correcting circuit 708 may perform a decoding procedure (hereinafter, also know as a hard-decision decoding procedure) for the hard-decision coding unit.

In the present exemplary embodiment, the hard-decision decoding procedure belongs to an iteration decoding procedure. For example, in the hard-decision decoding procedure, the error checking and correcting circuit 708 performs at least one iteration decoding calculation, so as to iteratively update reliability information (e.g., a decoding initial value) of at least one bit in the hard-decision coding unit to improve a decoding success rate of the hard-decision coding unit. The iteration decoding calculation performed each time may include a decoding operation identical or similar to that introduced in the exemplary embodiment of FIG. 10. According to a number of errors (also known as error bits) in the hard-decision coding unit, the hard-decision decoding procedure may either succeed or fail. For example, after the at least one iteration decoding calculation is performed, if the hard-decision decoding procedure succeeds (e.g., the error checking and correcting circuit 708 determines that all the errors in the hard-decision coding unit have been corrected), the error checking and correcting circuit 708 outputs the decoded hard-decision coding unit. For example, the decoded hard-decision coding unit may be transmitted to the host system 11 or may be used to perform other operations (e.g., storing back to the original memory cells or other memory cells in the rewritable non-volatile memory module 406). Otherwise, if the number of the error bits in the hard-decision coding unit is too many and/or the distributions of the error bits are located at positions hard to be corrected, the error checking and correcting circuit 708 may determine that the hard-decision decoding procedure fails in response to that a number of times that the iteration decoding calculation is performed reaches a predetermined number of times. Moreover, although the hard-decision decoding procedure belongs to the iteration decoding procedure in the present exemplary embodiment, however, it is possible that the hard-decision decoding procedure belongs to a non-iteration decoding procedure in another exemplary embodiment.

If the hard-decision decoding procedure fails, the memory management circuit 702 sends another read command sequence (hereinafter, also known as a first soft-decision read command sequence) to the rewritable non-volatile memory module 406. The first soft-decision read command sequence is configured to instruct reading data from the first memory cells according to another read voltage level (hereinafter, also known as a first soft-decision read voltage level). For example, the first soft-decision read voltage level may be assigned in the first soft-decision read command sequence or obtained through the table look-up approach by the rewritable non-volatile memory module 406 according to the first soft-decision read command sequence.

After receiving the first soft-decision read command sequence, the rewritable non-volatile memory module 406 reads the first memory cells by using the first soft-decision read voltage level to obtain another coding unit (hereinafter, also known as a first soft-decision coding unit). For example, according to the first soft-decision read command sequence, the rewritable non-volatile memory module 406 applies one read voltage corresponding to the first soft-decision read voltage level to the first memory cells so that a plurality of bit data may be transmitted back accordingly. The first soft-decision coding unit is constituted by aforesaid bit data. The first soft-decision coding unit belongs to the block code. Then, the error checking and correcting circuit 708 may perform another decoding procedure (hereinafter, also know as a first soft-decision decoding procedure) for the first soft-decision coding unit.

If the first soft-decision decoding procedure succeeds, the error checking and correcting circuit 708 outputs the decoded first soft-decision coding unit. For example, the decoded first soft-decision coding unit may be transmitted to the host system 11 or may be used to perform other operations. However, if the first soft-decision decoding procedure fails, the memory management circuit 702 sends another read command sequence (hereinafter, also known as a second soft-decision read command sequence) to the rewritable non-volatile memory module 406. The second soft-decision read command sequence is configured to instruct reading data from the first memory cells according to another read voltage level (hereinafter, also known as a second soft-decision read voltage level). After receiving the second soft-decision read command sequence, the rewritable non-volatile memory module 406 reads the first memory cells by using the second soft-decision read voltage level to obtain another coding unit (hereinafter, also known as a second soft-decision coding unit). For example, according to the second soft-decision read command sequence, the rewritable non-volatile memory module 406 applies one read voltage corresponding to the second soft-decision read voltage level to the first memory cells so that a plurality of bit data may be transmitted back accordingly. The second soft-decision coding unit is constituted by aforesaid bit data. The second soft-decision coding unit belongs to the block code. Then, the error checking and correcting circuit 708 may perform another decoding procedure (hereinafter, also know as a second soft-decision decoding procedure) for the second soft-decision coding unit.

In an exemplary embodiment, other soft-decision decoding procedures may be further performed between the first soft-decision decoding procedure and the second soft-decision decoding procedure. For example, in an exemplary embodiment, after the first soft-decision decoding procedure fails, another soft-decision read voltage level may be used to read the first memory cells in order to obtain another soft-decision coding unit, and another soft-decision decoding procedure (hereinafter, also known as a third soft-decision decoding procedure) may also be performed later. In this case, operations for obtaining the second soft-decision coding unit and performing the second soft-decision decoding procedure are performed after the third soft-decision decoding procedure fails. Herein, more or less of the soft-decision read voltage levels may be determined and used and more or less of the soft-decision decoding procedures may be performed, which are not particularly limited in the disclosure.

It is worth mentioning that, terms like “hard-decision” and “soft-decision” as mentioned in the exemplary embodiments of the present disclosure are simply used to distinguish the corresponding reading operations and decoding operations. For example, in an exemplary embodiment, the soft-decision decoding procedure is always performed only after the hard-decision decoding procedure fails. However, in another exemplary embodiment, if it is already identified that a difficulty for decoding one particular encoded data is higher according to the channel status (e.g., a wear degree or a threshold voltage distribution of the memory cells), then the hard-decision decoding procedure may not be performed but the soft-decision coding unit is directly read and the corresponding soft-decision coding unit is performed instead.

In the present exemplary embodiment, a difference value between the first soft-decision read voltage level and the second soft-decision read voltage level is related to the wear degree of the first memory cells. For example, the wear degree of the first memory cells is related to a usage status or a current operation environment of the first memory cells. For example, if a reading count of the first memory cells, a writing count of the first memory cells or/and an erasing count of the first memory cells are increased, the wear degree of the first memory cells may also be increased correspondingly. For example, if a time interval for storing the data in the first memory cells is increased, the wear degree of the first memory cells may also be increased correspondingly. For example, if a temperature or a humidity in the current operation environment of the rewritable non-volatile memory module 406 is overly high, the wear degree of the first memory cells may also be increased correspondingly. In addition, the wear degree of the first memory cells may also be related to the correctness/the error rate of the data stored in the first memory cells. For example, if the wear degree of the first memory cells is higher, the correctness of the data stored in the first memory cells is lower or the error rate (e.g., bit error rate) of the data stored in the first memory cells is higher. In an exemplary embodiment, the wear degree of the first memory cells may be represented by using a wear degree value. The wear degree value may be positively correlated or negatively correlated to the wear degree of the first memory cells. For example, if the wear degree value being greater indicates that the wear degree of the first memory cells is higher, then the wear degree value is positively correlated to the wear degree of the first memory cells; and if the wear degree value being greater indicates that the wear degree of the first memory cells is lower, then the wear degree value is negatively correlated to the wear degree of the first memory cells. In the present exemplary embodiment, the memory management circuit 702 determines the first soft-decision read voltage level and the second soft-decision read voltage level according to the wear degree (e.g., the wear degree value) of the first memory cells. The difference value between the first soft-decision read voltage level and the second soft-decision read voltage level is negatively correlated to the wear degree of the first memory cells. In other words, if the wear degree of the first memory cells is higher, the difference value between the first soft-decision read voltage level and the second soft-decision read voltage level is smaller; and if the wear degree of the first memory cells is lower, the difference value between the first soft-decision read voltage level and the second soft-decision read voltage level is greater.

In general, the wear degree of the memory cells often influences the threshold voltage distribution of the memory cells. Accordingly, in an exemplary embodiment, the memory management circuit 702 determines the first soft-decision read voltage level and the second soft-decision read voltage level according to a voltage distribution state (i.e., a threshold voltage distribution state) of the first memory cells. The voltage distribution state of the first memory cells may be obtained by scanning at least a part of the first memory cells, looking up tables according to the wear degree of the memory cells, or analyzing errors counted in one specific decoding procedure (e.g., the hard-decision decoding procedure). However, how to obtain the voltage distribution state of the first memory cells is not limited in the disclosure. Further, in an exemplary embodiment, the memory management circuit 702 determines the first soft-decision read voltage level and the second soft-decision read voltage level by analyzing a complete voltage distribution state of the first memory cells. However, in another exemplary embodiment, the memory management circuit 702 determines the first soft-decision read voltage level and the second soft-decision read voltage level simply by analyzing a voltage distribution state of the first memory cells at areas where the error rate is higher (e.g., the area 913 shown in FIG. 9) without obtaining the complete voltage distribution state of the first memory cells, so as to save an operating time.

In an exemplary embodiment, the memory management circuit 702 may determine the first soft-decision read voltage level and the second soft-decision read voltage level according to a gap width between adjacent two states (also known as a first state and a second state) in the voltage distribution state of the first memory cells and/or an overlapping degree between said two states. For example, in an exemplary embodiment, the gap width between the adjacent two states in the voltage distribution state of the first memory cells is positively correlated to the difference value between the first soft-decision read voltage level and the second soft-decision read voltage level. For example, if the gap width between the first state and the second state is greater, the difference value between the first soft-decision read voltage level and the second soft-decision read voltage level is also greater. The gap width may also refer to a distance between highest peaks of the adjacent two states, or refer to a distance between adjacent two ends (e.g., a right end of the distribution 901 and a left end of the distribution 902 in FIG. 9) of the adjacent two states. Further, in an exemplary embodiment, the overlapping degree between the adjacent two states in the voltage distribution state of the first memory cells is negatively correlated to the difference value between the first soft-decision read voltage level and the second soft-decision read voltage level. For example, if the overlapping degree between the first state and the second state is higher (e.g., when the number of the memory cells in the overlapping area 913 in FIG. 9 increases), then the difference value between the first soft-decision read voltage level and the second soft-decision read voltage level is less.

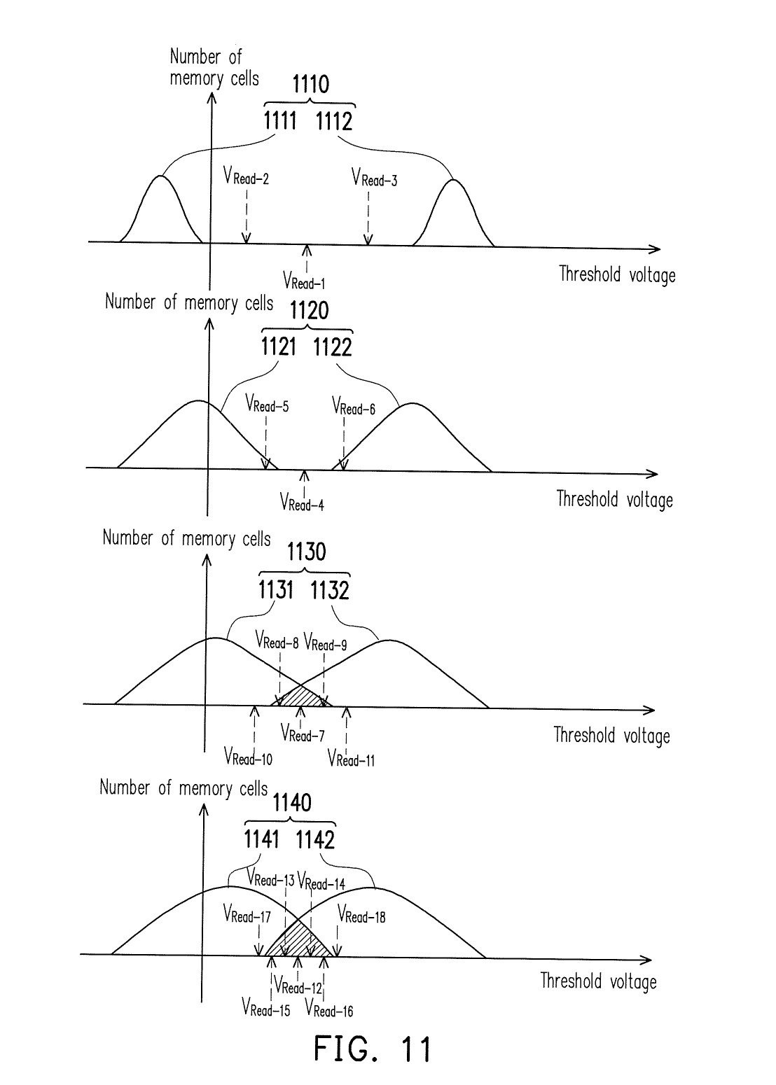

FIG. 11 is a schematic diagram illustrating the soft-decision read voltage levels and the threshold voltage distribution states of the memory cells according to an exemplary embodiment of the disclosure.

Referring to FIG. 11, it is assumed that each of the first memory cells is configured to store one bit data and the voltage distribution state of the first memory cells at four time-points (i.e., a first time-point, a second time-point, a third time-point and a fourth tune-point) are voltage distribution states 1110, 1120, 1130 and 1140 respectively.

In the present exemplary embodiment, a gap width between states 1121 and 1122 in the voltage distribution state 1120 is less than a gap width between states 1111 and 1112 in the voltage distribution state 1110. Therefore, a difference value between any adjacent two soft-decision read voltage levels among usable soft-decision read voltage levels V_{Read-4} to V_{Read-6} corresponding to the voltage distribution state 1120 is less than a difference value between any adjacent two soft-decision read voltage levels among usable soft-decision read voltage levels V_{Read-1} to V_{Read-3} corresponding to the voltage distribution state 1110.

In the present exemplary embodiment, the states 1131 and 1132 in the voltage distribution state 1130 are overlapped with each other, so that there is no gap provided between the states 1131 and 1132 (i.e., a gap width thereof is zero). Therefore, a difference value between any adjacent two soft-decision read voltage levels among usable soft-decision read voltage levels V_{Read-7} to V_{Read-11} corresponding to the voltage distribution state 1130 is less than a difference value between any adjacent two soft-decision read voltage levels among the usable soft-decision read voltage levels V_{Read-4} to V_{Read-6} corresponding to the voltage distribution state 1120.

In the present exemplary embodiment, an overlapping degree between states 1141 and 1142 in the voltage distribution state 1140 is greater than an overlapping degree between states 1131 and 1132 in the voltage distribution state 1130. Therefore, a difference value between any adjacent two soft-decision read voltage levels among usable soft-decision read voltage levels V_{Read-12} to V_{Read-18} is less than a difference value between any adjacent two soft-decision read voltage levels among the usable soft-decision read voltage levels V_{Read-7} to V_{Read-11}.

In general, if the gap width between the adjacent states in the voltage distribution state of the memory cells is smaller or the overlapping degree between the adjacent states is higher, the number of the error bits in the data read from the memory cells is usually greater, and thus the number of times that the soft-decision decoding procedure being performed may be increased in order to successfully decode the read data. Therefore, in an exemplary embodiment, besides reducing the difference value between the adjacent soft-decision read voltage levels being used, a decoding success rate may also be increased by increasing the number of the usable soft-decision read voltage levels. For example, in the exemplary embodiment of FIG. 11, because the overlapping degree between the states 1141 and 1142 in the voltage distribution state 1140 is greater than the overlapping degree between the states 1131 and 1132 in the voltage distribution state 1130, the number of usable soft-decision read voltage levels V_{Read-12} to V_{Read-18} corresponding to the voltage distribution state 1140 is set be greater than the number of the usable soft-decision read voltage levels V_{Read-7} to V_{Read-11} corresponding to the voltage distribution state 1130. By analogy, in another exemplary embodiment, as the gap width between the adjacent states changes, the number of the soft-decision read voltage levels corresponding thereto may also be increased or reduced.

In an exemplary embodiment, the soft-decision read voltage levels determined in correspondence to the current voltage state and the current wear degree of the first memory cells may be regarded as belonging to the same soft-decision read voltage level group. The difference value between any adjacent two soft-decision read voltage levels among the soft-decision read voltage levels that belong to the same soft-decision read voltage level group may be identical to or different from the other different values in the same soft-decision read voltage level group. If the hard-decision decoding procedure fails, the soft-decision read voltage levels in the corresponding soft-decision read voltage level group may be used one by one to read the corresponding soft-decision coding unit. For example, taking the soft-decision read voltage levels V_{Read-12} to V_{Read-18} of FIG. 11 as an example, if the hard-decision decoding procedure fails, the soft-decision read voltage level V_{Read-12} is the first to be used for reading the first memory cells and one soft-decision decoding procedure corresponding thereto is performed; if the performed soft-decision decoding procedure fails, the soft-decision read voltage level V_{Read-13} is the next to be used for reading the first memory cells and one soft-decision decoding procedure corresponding thereto is executed; if the performed soft-decision decoding procedure still fails, the soft-decision read voltage level V_{Read-14} is the next to be used for reading the first memory cells and one soft-decision decoding procedure corresponding thereto is executed; if the performed soft-decision decoding procedure still fails, the soft-decision read voltage level V_{Read-15} is the next to be used for reading the first memory cells and one soft-decision decoding procedure corresponding thereto is executed; if the performed soft-decision decoding procedure still fails, the soft-decision read voltage level V_{Read-16} is the next to be used for reading the first memory cells and one soft-decision decoding procedure corresponding thereto is executed, and so on until one specific soft-decision decoding procedure succeeds or all of the soft-decision read voltage levels in the soft-decision read voltage level group have been used. In addition, a usage order the soft-decision read voltage levels belonging to the same soft-decision read voltage level group is not particularly limited in the disclosure. For example, in another exemplary embodiment, the soft-decision read voltage levels V_{Read-12} to V_{Read-18} are sequentially used according to the voltage values (e.g., form the smallest to the largest) or any rules.

In an exemplary embodiment, the soft-decision read voltage levels that belong to the same soft-decision read voltage level group may be determined at once. For example, according to the wear degree of the first memory cells, a look-up table recorded with the corresponding soft-decision read voltage level group may be selected or generated so that all the soft-decision read voltage levels in said soft-decision read voltage level group may be obtained at once. However, in another exemplary embodiment, each of the soft-decision read voltage levels that belong to the same soft-decision read voltage level group is instantly determined only when use of the corresponding one of the soft-decision read voltage levels is required. For example, in an exemplary embodiment, if the hard-decision decoding procedure fails, only the soft-decision read voltage level V_{Read-12} is first determined and used; and later, if the soft-decision decoding procedure corresponding to the soft-decision read voltage level V_{Read-12} fails, the next soft-decision read voltage level that belongs to the same soft-decision read voltage level group is then determined and used.

In an exemplary embodiment, if the hard-decision decoding procedure fails, the memory management circuit 702 performs an optimal read voltage level tracking process to determine an optimal read voltage level corresponding to the first memory cells. For example, according to the exemplary embodiment of FIG. 11, in the voltage distribution state 1110, the optimal read voltage level corresponding to the first memory cells may be the soft-decision read voltage level V_{Read-1}; in the voltage distribution state 1120, the optimal read voltage level corresponding to the first memory cells may be the soft-decision read voltage level V_{Read-4}; in the voltage distribution state 1130, the optimal read voltage level corresponding to the first memory cells may be the soft-decision read voltage level V_{Read-7}; and in the voltage distribution state 1140, the optimal read voltage level corresponding to the first memory cells may be the soft-decision read voltage level V_{Read-12}. The other soft-decision read voltage levels that belong to the same soft-decision read voltage level group may be set according to the optimal read voltage level. For example, in an exemplary embodiment, the memory management circuit 702 may determine the difference value between any adjacent two soft-decision read voltage levels according to the wear degree or the voltage distribution state of the first memory cells. Details regarding how to determine the difference value between any adjacent two soft-decision read voltage levels according to the wear degree or the voltage distribution state of the first memory cells have been described above, which are not repeated hereinafter. After the optimal read voltage level is obtained, the memory management circuit 702 may determine the other soft-decision read voltage levels one by one or at once according to the optimal read voltage level and the determined difference value. For example, according to the exemplary embodiment of FIG. 11, in the voltage state 1140, the optimal read voltage level corresponding to the first memory cells is the soft-decision read voltage level V_{Read-12}; after one specific difference value is determined, the soft-decision read voltage level V_{Read-13} may be obtained by subtracting the specific difference value from the soft-decision read voltage level V_{Read-12}, and the soft-decision read voltage level V_{Read-14} may be obtained by adding the specific difference value to the voltage level V_{Read-12}. In another exemplary embodiment, the determined difference value may also be a difference value between the soft-decision read voltage levels respectively having a largest voltage value and a smallest voltage value in the same soft-decision read voltage level group. For example, in an exemplary embodiment of FIG. 11, the memory management circuit 702 may determine a difference value between the soft-decision read voltage levels V_{Read-17} and V_{Read-18} according to the wear degree or the voltage distribution state of the first memory cells. Then, the memory management circuit 702 may set the soft-decision read voltage levels V_{Read-12} to V_{Read-18} according to the soft-decision read voltage level V_{Read-12} and the difference value between the soft-decision read voltage level V_{Read-17} and V_{Read-18}. In addition, in another exemplary embodiment, the determined difference value may also be a difference value between any non-adjacent two soft-decision read voltage levels.

In an exemplary embodiment, one of the first soft-decision read voltage level and the second soft-decision read voltage level is the optimal read voltage level corresponding to the first memory cells. More specifically, one of the first soft-decision read voltage level and the second soft-decision read voltage level is corresponding to an optimal read voltage level corresponding to the current voltage distribution state of the first memory cells, and another one of the first soft-decision read voltage level and the second soft-decision read voltage level is a soft-decision read voltage level adjacent to said optimal read voltage level. However, in another exemplary embodiment, the first soft-decision read voltage level and the second soft-decision read voltage level may refer to any adjacent two soft-decision read voltage levels in the same soft-decision read voltage level group corresponding to the current voltage distribution state of the first memory cells (e.g., the soft-decision read voltage levels V_{Read-1} and V_{Read-2} in FIG. 11). Alternatively, in another exemplary embodiment, the first soft-decision read voltage level and the second soft-decision read voltage level may also refer to any non-adjacent two soft-decision read voltage levels in the same soft-decision read voltage level group corresponding to the current voltage distribution state of the first memory cells (e.g., the soft-decision read voltage levels V_{Read-2} and V_{Read-3} in FIG. 11).

Referring back to FIG. 10, in view of the exemplary embodiment of FIG. 10, it can be known that either one or both of the first-type decoding procedure corresponding to one specific row and the second-type decoding procedure corresponding to one specific column may succeed or fail. The first-type decoding procedure performed each time is independent to each other, and the second-type decoding procedure performed each time is also independent to each other. For example, the first-type decoding procedure for the sub coding unit 1020(1) may succeed or fail and the first-type decoding procedure for the sub coding unit 1020(2) may also succeed or fail, and these two results may not be related. Therefore, even if the decoding procedure for one specific coding unit fails, the specific coding unit may still include the rows, the columns or the bits which are successfully decoded.

In an exemplary embodiment, in the process of performing the decoding procedure, a part of bit values on the successfully decoded (or corrected) positions may be regarded as corrected bit values to be recorded. For example, in the first soft-decision decoding procedure, if one specific row or column is successfully decoded, the bit value on each position in the specific row or column may be recorded. Later, if the first soft-decision decoding procedure fails, the memory management circuit 702 sets at least one bit in the obtained second soft-decision coding unit as at least one bit value previously determined (or corrected) in the first soft-decision decoding procedure (or the hard-decision decoding procedure) before the second soft-decision decoding procedure is performed. For example, in the exemplary embodiment of FIG. 10, assuming that a decoding for coding unit 1010 fails but the decoding result of the decoding indicates that the bit b₁₁ in the coding unit 1010 is correct, then the bit value of the bit b₁₁ is then recorded. Later, after the read voltage level is adjusted for reading the same data, in the next decoding performed on the read data, the bit b₁₁ on the same position in the read coding unit may be directly corrected to as the previously recorded bit value. In other words, during performing the decoding procedures according to the different read voltage levels, a part of the bits successfully decoded in the previous decoding procedure in the coding unit obtained each time may be gradually determined (e.g., corrected). For example, in the exemplary embodiment of FIG. 11, after a part of soft-decision read voltage levels among the soft-decision read voltage levels V_{Read-12} to V_{Read-18} is used one by one to read the soft-decision coding units and the corresponding soft-decision decoding procedures are performed, even if the currently performed soft-decision decoding procedure still fails, the bits still need to be decoded (i.e., the bits which are not successfully decoded yet) is gradually decreased in the next soft-decision decoding procedure. Accordingly, the decoding success rate may be gradually increased in the next soft-decision decoding procedure. Further, the disclosure is not intended to limit a type of the additional decoding information to be passed along, and any decoding information that can be passed to the next decoding procedure may be recorded and adopted in the next decoding procedure.

In an exemplary embodiment, at least a part of the bits successfully decoded in the hard-decision decoding procedure may also be applied in the subsequently performed soft-decision decoding procedures (e.g., the first soft-decision decoding procedure and/or the second soft-decision decoding procedure). Accordingly, even if the previously performed hard-decision decoding procedure and the soft-decision decoding procedures all failed, these failed decoding procedures can still contribute the following decoding procedures.

It is worth mentioning that, in an exemplary embodiment, a data size of the hard-decision coding unit obtained by using the hard-decision read voltage level is equal to a data size of the soft-decision coding unit subsequently obtained each time by using the soft-decision read voltage levels. Therefore, in the foregoing exemplary embodiments, it is not required to increase a size of a temporary area configured to temporarily store the hard-decision coding unit and the soft-decision coding unit in response to switching from the hard-decision decoding procedure to the soft-decision decoding procedure. Furthermore, in the foregoing exemplary embodiments, the algorithm/decoding rule used by the soft-decision decoding procedure is identical to similar to the algorithm/decoding rule used by the hard-decision decoding procedure, which is not repeated hereinafter.

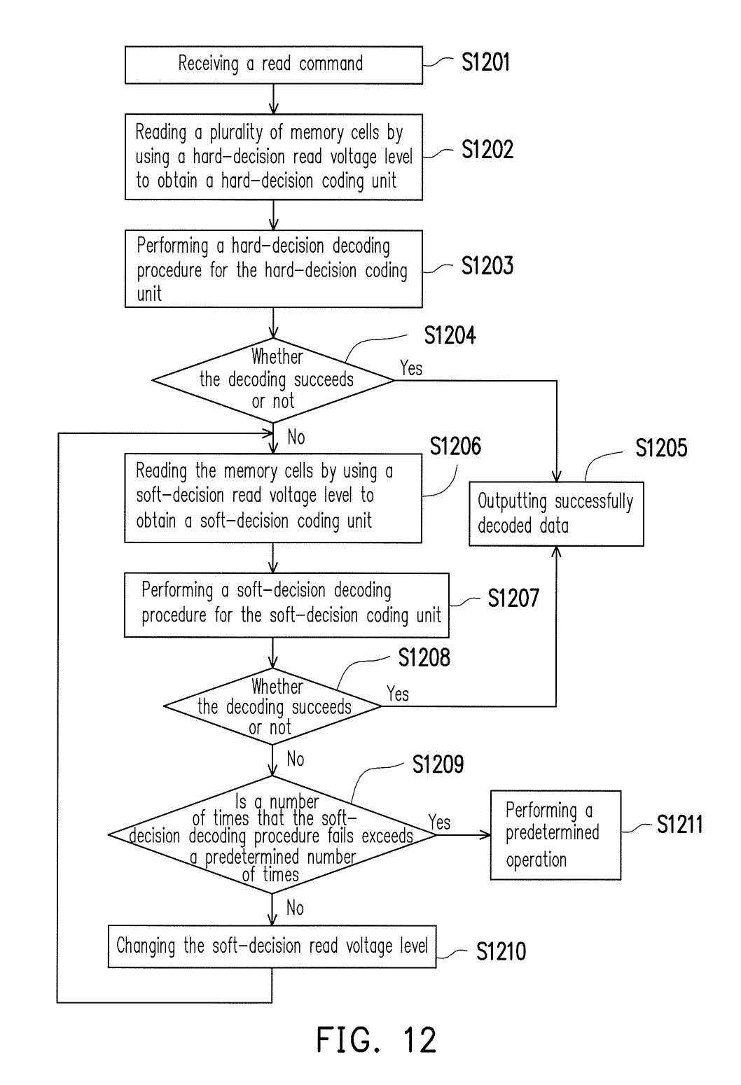

FIG. 12 is a flowchart illustrating a decoding method according to an exemplary embodiment of the disclosure. Referring to FIG. 12, in a step S1201, a read command is received. In step S1202, a plurality of memory cells (e.g., the first memory cells) in a rewritable non-volatile memory module are read by using a hard-decision read voltage level to obtain a hard-decision coding unit. The hard-decision coding unit belongs to the block code. In step S1203, a hard-decision decoding procedure is performed for the hard-decision coding unit. In step S1204, whether the hard-decision decoding procedure succeeds is determined. If the hard-decision decoding procedure succeeds, in step S1205, successfully decoded data (i.e., the hard-decision coding unit that is successfully decoded) is outputted. If the hard-decision decoding procedure does not succeed (i.e., it fails), in step S1206, the memory cells (e.g., the first memory cell) are read by using a soft-decision read voltage level to obtain a soft-decision coding unit. The soft-decision coding unit also belongs to the block code. In step S1207, a soft-decision decoding procedure is performed for the soft-decision coding unit. In step S1208, whether the soft-decision decoding procedure succeeds is determined. If the performed soft-decision decoding procedure succeeds, proceeding to perform step S1205. If the performed soft-decision decoding procedure does not succeed (i.e., it fails), in step S1209, whether a number of times that the soft-decision decoding procedure fails exceeds a predetermined number of times is determined. If the number of times that the soft-decision decoding procedure fails does not exceed the predetermined number of times (e.g., there are still one or more soft-decision read voltage levels could be used), in step S1210, the soft-decision read voltage level to be used is changed, and then step S1206 is repeatedly performed according to the changed soft-decision read voltage level. For example, in step S1210, if the soft-decision read voltage level to be used is changed from the first soft-decision read voltage level used in step S1206 into the second soft-decision read voltage level that has the larger or smaller voltage values than that of the first soft-decision read voltage level, the second soft-decision read voltage level is used to re-read the memory cells (e.g., the first memory cells) in step S1206. In addition, if the number of times that the soft-decision decoding procedure fails exceeds the predetermined number of times (e.g., all of the soft-decision decoding procedures have been used), in step S1211, a predetermined operation is performed. For example, the predetermined operation may include transmitting a read failure message to the host system and/or performing other error handling procedure.

It is worth mentioning that, in the exemplary embodiment of FIG. 12, all the usable soft-decision read voltage levels are determined (e.g., by looking up tables or by algorithm calculations) according to the wear degree of the memory cells (e.g., the first memory cells) to be read. Each of the usable soft-decision read voltage levels may be determined together or may be determined respectively when use of the corresponding one of the soft-decision read voltage levels is required. Nevertheless, steps depicted in FIG. 12 are described in detail as above, thus related description is omitted hereinafter. It should be noted that, the steps depicted in FIG. 12 may be implemented as a plurality of program codes or circuits, which are not particularly limited in the disclosure. Moreover, the method disclosed in FIG. 12 may be implemented by reference with above exemplary embodiments, or may be implemented separately, which are not particularly limited in the disclosure.

In summary, the disclosure is capable of respectively reading the first soft-decision coding unit and second soft-decision coding unit both belonging to the block code by using the first soft-decision read voltage level and the second soft-decision read voltage level according to the wear degree of the memory cells, and performing the corresponding soft-decision decoding procedures. Accordingly, a decoding efficiency of block codes may be improved. The previously described exemplary embodiments of the present disclosure have the advantages aforementioned, wherein the advantages aforementioned not required in all versions of the disclosure.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A decoding method for a rewritable non-volatile memory module comprising a plurality of memory cells, and the decoding method comprising:
determining a first soft-decision read voltage level and a second soft-decision read voltage level according to a wear degree of a plurality of first memory cells among the memory cells, wherein a difference value is provided between the first soft-decision read voltage level and the second soft-decision read voltage level;
reading the first memory cells by using the first soft-decision read voltage level to obtain a first soft-decision coding unit, wherein the first soft-decision coding unit belongs to a block code;
performing a first soft-decision decoding procedure for the first soft-decision coding unit;
if the first soft-decision decoding procedure fails, reading the first memory cells by using the second soft-decision read voltage level to obtain a second soft-decision coding unit, wherein the second soft-decision coding unit belongs to the block code; and
performing a second soft-decision decoding procedure for the second soft-decision coding unit.

2. The decoding method of claim 1, further comprising:
receiving a read command and reading the first memory cells by using a hard-decision read voltage level to obtain a hard-decision coding unit, wherein the hard-decision coding unit belongs to the block code; and
performing a hard-decision decoding procedure for the hard-decision coding unit,
wherein the step of reading the first memory cells by using the first soft-decision read voltage level is performed after the hard-decision decoding procedure fails.

3. The decoding method of claim 1, further comprising:
setting at least one bit in the second soft-decision coding unit as at least one bit value corrected in the first soft-decision decoding procedure before performing the second soft-decision decoding procedure.

4. The decoding method of claim 1, wherein the step of determining the first soft-decision read voltage level and the second soft-decision read voltage level according to the wear degree of the first memory cells comprises:
obtaining a voltage distribution state of the first memory cells, wherein the voltage distribution state at least comprises a first state and a second state; and
determining the first soft-decision read voltage level and the second soft-decision read voltage level according to a gap width between the first state and the second state or an overlapping degree between the first state and the second state.

5. The decoding method of claim 4, wherein the difference value between the first soft-decision read voltage level and the second soft-decision read voltage level is negatively correlated to the overlapping degree between the first state and the second state.

6. The decoding method of claim 4, wherein the difference value between the first soft-decision read voltage level and the second soft-decision read voltage level is positively correlated to the gap width between the first state and the second state.

7. The decoding method of claim 1, wherein the difference value between the first soft-decision read voltage level and the second soft-decision read voltage level is negatively correlated to the wear degree of the first memory cells,
wherein the step of determining the first soft-decision read voltage level and the second soft-decision read voltage level according to the wear degree of the first memory cells comprises:
determining the first soft-decision read voltage level and the second soft-decision read voltage level according to at least one of a reading count of the first memory cells, a writing count of the first memory cells, an erasing count of the first memory cells and a bit error rate of the first memory cells.

8. The decoding method of claim 1, wherein one of the first soft-decision read voltage level and the second soft-decision read voltage level is an optimal read voltage level corresponding to the first memory cells,
wherein the step of determining the first soft-decision read voltage level and the second soft-decision read voltage level according to the wear degree of the first memory cells comprises:
performing an optimal read voltage level tracking process to determine the optimal read voltage level.

9. The decoding method of claim 1, wherein the block code is constituted by a plurality of sub coding units, wherein a predetermined bit of the sub coding units is determined by a plurality of encoding procedures.

10. The decoding method of claim 9, wherein the encoding procedures have different encoding directions.

11. A memory storage device, comprising:
a connection interface unit, configured to couple to a host system;
a rewritable non-volatile memory module comprising a plurality of memory cells; and
a memory control circuit unit, coupled to the connection interface unit and the rewritable non-volatile memory module,
wherein the memory control circuit unit is configured to determine a first soft-decision read voltage level and a second soft-decision read voltage level according to a wear degree of a plurality of first memory cells among the memory cells, wherein a difference value is provided between the first soft-decision read voltage level and the second soft-decision read voltage level,
wherein the memory control circuit unit is further configured to send a first soft-decision read command sequence, wherein the first soft-decision read command sequence is configured to instruct reading the first memory cells by using the first soft-decision read voltage level to obtain a first soft-decision coding unit, wherein the first soft-decision coding unit belongs to a block code,
wherein the memory control circuit unit is further configured to perform a first soft-decision decoding procedure for the first soft-decision coding unit,
wherein the memory control circuit unit is further configured to send a second soft-decision read command sequence if the first soft-decision decoding procedure fails, wherein the second soft-decision read command sequence is configured to instruct reading the first memory cells by using the second soft-decision read voltage level to obtain a second soft-decision coding unit, wherein the second soft-decision coding unit belongs to the block code,
wherein the memory control circuit unit is further configured to perform a second soft-decision decoding procedure for the second soft-decision coding unit.

12. The memory storage device of claim 11, wherein the memory control circuit unit is further configured to receive a read command and send a hard-decision read command sequence, wherein the hard-decision read command sequence is configured to instruct reading the first memory cells by using a hard-decision read voltage level to obtain a hard-decision coding unit, wherein the hard-decision coding unit belongs to the block code,
wherein the memory control circuit unit is further configured to perform a hard-decision decoding procedure for the hard-decision coding unit,
wherein the operation of sending the first soft-decision read command sequence by the memory control circuit unit is performed after the hard-decision decoding procedure fails.

13. The memory storage device of claim 11, wherein the memory control circuit unit is further configured to set at least one bit in the second soft-decision coding unit as at least one bit value corrected in the first soft-decision decoding procedure before performing the second soft-decision decoding procedure.

14. The memory storage device of claim 11, wherein the operation of determining the first soft-decision read voltage level and the second soft-decision read voltage level by the memory control circuit unit according to the wear degree of the first memory cells comprises:
obtaining a voltage distribution state of the first memory cells, wherein the voltage distribution state at least comprises a first state and a second state; and
determining the first soft-decision read voltage level and the second soft-decision read voltage level according to a gap width between the first state and the second state or an overlapping degree between the first state and the second state.

15. The memory storage device of claim 14, wherein the difference value between the first soft-decision read voltage level and the second soft-decision read voltage level is negatively correlated to the overlapping degree between the first state and the second state.

16. The memory storage device of claim 14, wherein the difference value between the first soft-decision read voltage level and the second soft-decision read voltage level is positively correlated to the gap width between the first state and the second state.

17. The memory storage device of claim 11, wherein the difference value between the first soft-decision read voltage level and the second soft-decision read voltage level is negatively correlated to the wear degree of the first memory cells,
wherein the operation of determining the first soft-decision read voltage level and the second soft-decision read voltage level by the memory control circuit unit according to the wear degree of the first memory cells comprises:
determining the first soft-decision read voltage level and the second soft-decision read voltage level according to at least one of a reading count of the first memory cells, a writing count of the first memory cells, an erasing count of the first memory cells and a bit error rate of the first memory cells.

18. The memory storage device of claim 11, wherein one of the first soft-decision read voltage level and the second soft-decision read voltage level is an optimal read voltage level corresponding to the first memory cells,
wherein the operation of determining the first soft-decision read voltage level and the second soft-decision read voltage level by the memory control circuit unit according to the wear degree of the first memory cells comprises:
performing an optimal read voltage level tracking process to determine the optimal read voltage level.

19. The memory storage device of claim 11, wherein the block code is constituted by a plurality of sub coding units, and a predetermined bit of the sub coding units is determined by a plurality of encoding procedures.

20. The memory storage device of claim 19, wherein the encoding procedures have different encoding directions.

21. A memory control circuit unit, configured to control a rewritable non-volatile memory module, wherein the rewritable non-volatile memory module comprises a plurality of memory cells, and the memory control circuit unit comprises:
a host interface, configured to couple to a host system;
a memory interface, configured to couple to the rewritable non-volatile memory module;
an error checking and correcting circuit; and
a memory management circuit, coupled to the host interface, the memory interface and the error checking and correcting circuit,
wherein the memory management circuit is configured to determine a first soft-decision read voltage level and a second soft-decision read voltage level according to a wear degree of a plurality of first memory cells among the memory cells, wherein a difference value is provided between the first soft-decision read voltage level and the second soft-decision read voltage level,
wherein the memory management circuit is further configured to send a first soft-decision read command sequence, wherein the first soft-decision read command sequence is configured to instruct reading the first memory cells by using the first soft-decision read voltage level to obtain a first soft-decision coding unit, wherein the first soft-decision coding unit belongs to a block code,
wherein the error checking and correcting circuit is configured to perform a first soft-decision decoding procedure for the first soft-decision coding unit,
wherein the memory management circuit is further configured to send a second soft-decision read command sequence if the first soft-decision decoding procedure fails, wherein the second soft-decision read command sequence is configured to instruct reading the first memory cells by using the second soft-decision read voltage level to obtain a second soft-decision coding unit, wherein the second soft-decision coding unit belongs to the block code,
wherein the error checking and correcting circuit is further configured to perform a second soft-decision decoding procedure for the second soft-decision coding unit.

22. The memory control circuit unit of claim 21, wherein the operation of determining the first soft-decision read voltage level and the second soft-decision read voltage level by the memory management circuit according to the wear degree of the first memory cells comprises:
obtaining a voltage distribution state of the first memory cells, wherein the voltage distribution state at least comprises a first state and a second state; and
determining the first soft-decision read voltage level and the second soft-decision read voltage level according to a gap width between the first state and the second state or an overlapping degree between the first state and the second state.

23. The memory control circuit unit of claim 22, wherein the difference value between the first soft-decision read voltage level and the second soft-decision read voltage level is negatively correlated to the overlapping degree between the first state and the second state.

24. The memory control circuit unit of claim 22, wherein the difference value between the first soft-decision read voltage level and the second soft-decision read voltage level is positively correlated to the gap width between the first state and the second state.

25. The memory control circuit unit of claim 21, wherein one of the first soft-decision read voltage level and the second soft-decision read voltage level is an optimal read voltage level corresponding to the first memory cells,
wherein the operation of determining the first soft-decision read voltage level and the second soft-decision read voltage level by the memory management circuit according to the wear degree of the first memory cells comprises:
performing an optimal read voltage level tracking process to determine the optimal read voltage level.
